(19) United States
(12) Patent Application Publication
(10) Pub. No.: US 2009/0021849 A1
(43) Pub. Date: Jan. 22, 2009

(54) Drive unit and method for making the drive unit

(75) Inventors: Kenichi Murakami, Toyokawa-shi (JP); Mitsuhiko Morita, Toyokawa-shi (JP)

Correspondence Address: COHEN, PONTANI, LIEBERMAN & PAVANE LLP, 551 FIFTH AVENUE, SUITE 1210, NEW YORK, NY, 10176, US

(73) Assignee: Konica Minolta Opto, Inc., Tokyo (JP)

(21) Appl. No.: 12/218,541

(22) Filed: Jul. 16, 2008

(30) Foreign Application Priority Data
Jul. 17, 2007 (JP) 2007-185750

(51) Int. Cl. G02B 7/04; H01L 41/22

(52) U.S. Cl. 359/824; 29/25.35

(57) ABSTRACT

Disclosed is a drive unit including an element for mechano-electric transduction; a driving member for causing a driven member to perform a predetermined motion according to a displacement of the element; and a housing for housing the driving member; wherein the housing includes an electrical terminal, and a loading section for loading the element, the electrical terminal being configured to be connectable with the element when the element is attached to the loading section.

### BACKGROUND OF THE INVENTION

1. Field of the Invention

The present invention relates to a drive unit having an imaging element, and to a method for making the drive unit.

2. Related Art

In recent years, a small-scale imaging unit (drive unit) that is mountable to various portable electronic devices has been developed with, for example, a camera-equipped cell-phone or the like has become widespread. An auto-focus imaging unit having zoom lens therein has also developed.

The imaging unit generally has a set of movable lens arranged in front of an imaging element having a rectangular imaging area. A light intensity controller such as a shutter or a diaphragm is arranged in front of the set of movable lens. Then, recently a drive unit having, for example, a Smooth Impact Driving Mechanism (SIDM: trademark), which is a liner actuator using rapid volume changes of a piezoelectric element, inertia and a frictional force of a mobile object, is adopted as a driver of the set of movable lens (see, for example, “KEITAI DENWA MUKE CHOU KOGATA ZOOM UNIT NO KAIHATSU”, KONICA MINOLTA TECHNOLOGY REPORT, vol. 4 (2007), p. 81, KONICA MINOLTA HOLDINGS LTD.).

The SIDM includes a main body configured by connecting three elements: a fixed portion, a piezoelectric element and a drive shaft, and a mobile object frictionally engaged with the drive shaft. The SIDM is adopted as a drive source of a zoom function for an imaging unit by making the mobile object hold the set of movable lens.

At this moment, a driving signal is input into the piezoelectric element of the SIDM through flexible printed circuits (FPC). The FPC is easy to fold and has a high general versatility according to the structure that an adhesion layer is formed on a film insulator, and a conductive foil is formed on the film insulator. However, it is unfortunately troublesome to decide an attaching direction, a length and a location of the FPC when attaching the FPC into the imaging unit. Moreover, the number of assembling processes unfortunately increases because of a need for soldering to connect the piezoelectric element with the FPC, or the like. Moreover, the FPC causes preventing the imaging unit from downsizing, because the FPC is attached to the imaging unit with being directed to an outward direction of the imaging unit so as to electrically be connected to the devices on which the imaging unit is mounted thereon.

### SUMMARY OF THE INVENTION

The present invention was made in view of the problem mentioned above.

It is, therefore, a main object of the present invention to provide a drive unit having movable lens being easy to assemble, and to provide a method for making the drive unit.

According to a first aspect of the present invention, there is provided a drive unit, including: an element for mechano-electric transduction; a driving member for causing a driven member to perform a predetermined motion according to a displacement of the element; and a housing for housing the driving member; wherein, the housing includes an electrical terminal, and a loading section for loading the element, the electrical terminal being configured to be connectable with the element when the element is attached to the loading section.

According to a second aspect of the present invention, there is provided a method for making the drive unit, including the steps of: a first step for configuring the housing integrally with the electrical terminal; and a second step for connecting the one end of the electrical terminal to the element by attaching the element to the loading section of the housing obtained by the first step.

### BRIEF DESCRIPTION OF THE DRAWINGS

The above and other objects, advantage and features of the present invention will become more fully understood from the detailed description given hereinbelow and the appended drawings which are given by way of illustration only, and thus are not intended as a definition of the limits of the present invention, and wherein:

FIG. 1A is a perspective view showing a front side of a cell-phone with a driving unit in accordance with an embodiment of the present invention;

FIG. 1B is a perspective view showing a rear side of the cell-phone with the driving unit in accordance with the embodiment;

FIG. 2 is a perspective view showing a whole configuration of an imaging unit in accordance with the embodiment;

FIG. 3 is a perspective view showing a partial configuration of an imaging unit in accordance with the embodiment;

FIG. 4 is an enlarged partial view of the imaging unit in accordance with the embodiment;

FIG. 5 is a front view showing the imaging unit in accordance with the embodiment;

FIG. 6 is a side view showing the imaging unit of FIG. 5;

FIG. 7A is an explanation drawing showing a manufacturing process (before assembling a main body) of the imaging unit in accordance with the embodiment;

FIG. 7B is an explanation drawing showing the manufacturing process (after inserting the main body) of the imaging unit in accordance with the embodiment; and

FIG. 7C is an explanation drawing showing the manufacturing process (after finishing an assembling of the main body) of the imaging unit in accordance with the embodiment.

### DETAILED DESCRIPTION OF THE PREFERRED EMBODIMENTS

In the following, a drive unit and a method for making the drive unit in accordance with an embodiment of the present invention will be described with reference to the attached drawings.

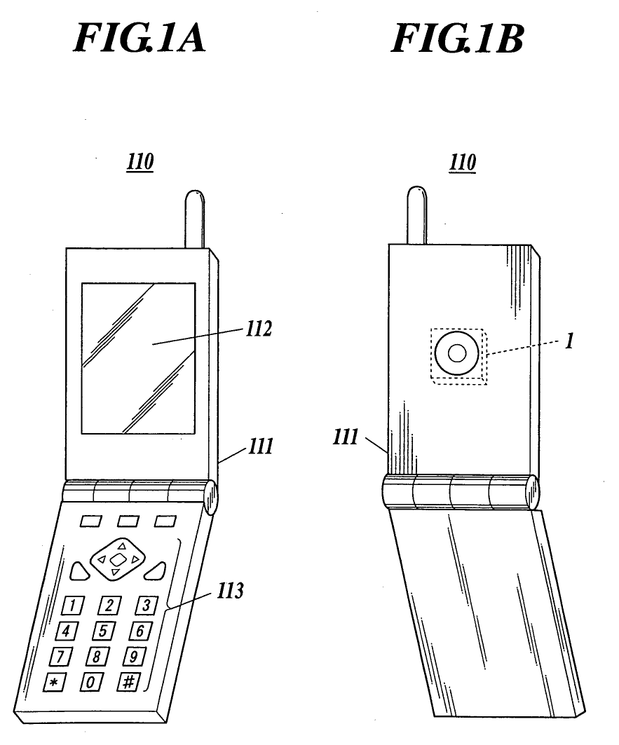

FIG. 1A and FIG. 1B show perspective views of a cell-phone 110, which is an example of an electronic device having an imaging unit 1 in a main frame as a drive unit in accordance with the present embodiment.

As shown in FIG. 1A and FIG. 1B, a cell-phone 110 includes an imaging unit 1 having an imaging device in a main frame 111. The cell-phone 110 further includes a display 112 for displaying an image taken by the imaging unit 1, an operating section 113 for various operations, and so on.

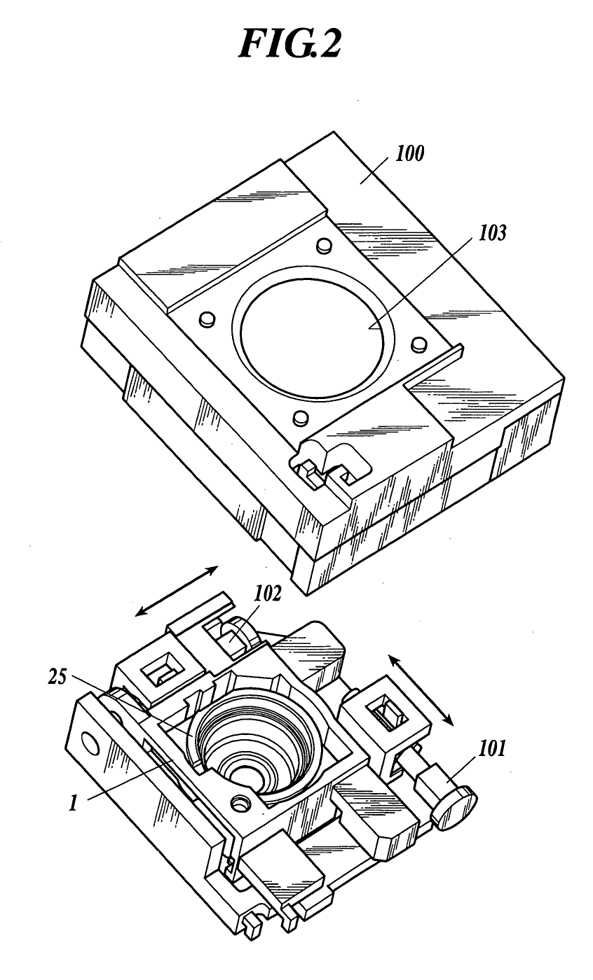

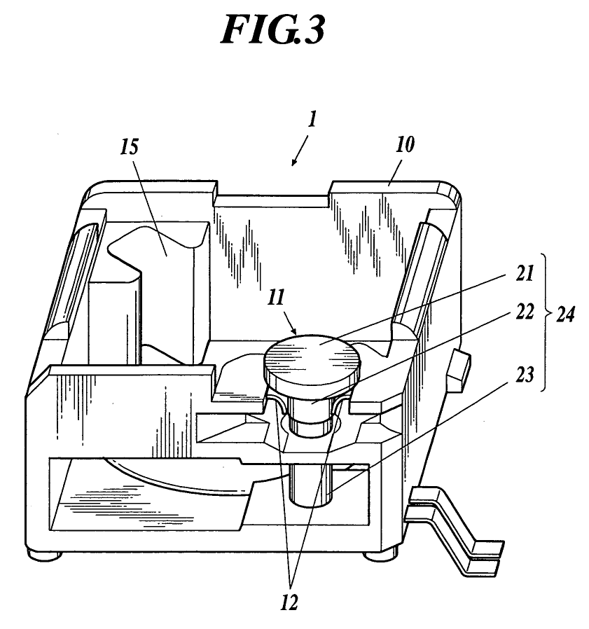

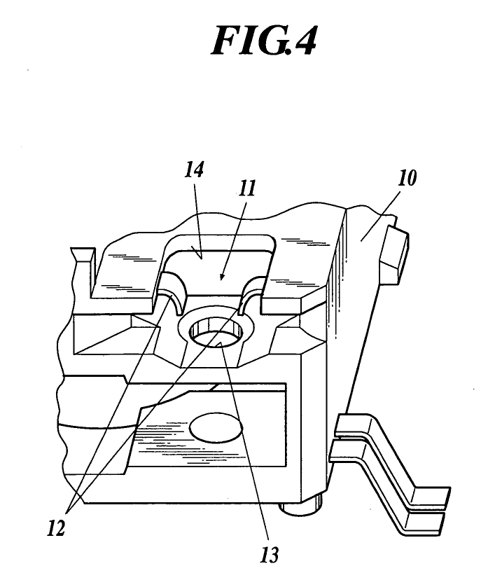

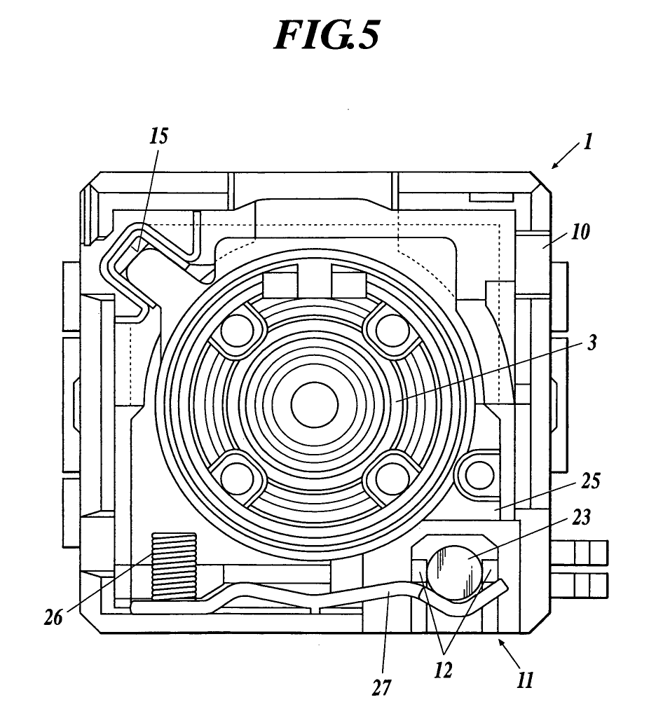

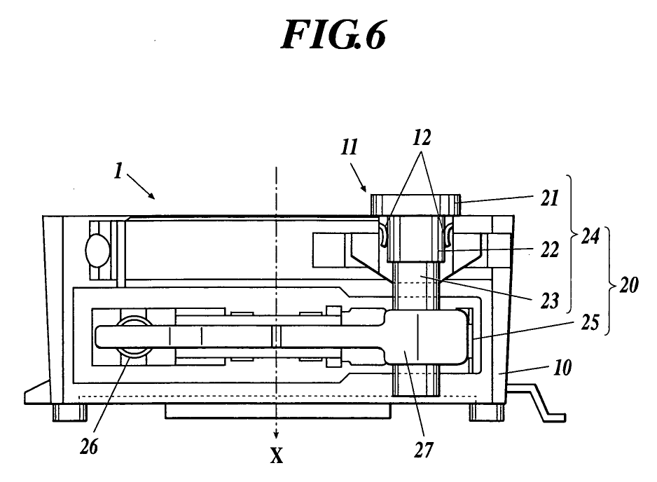

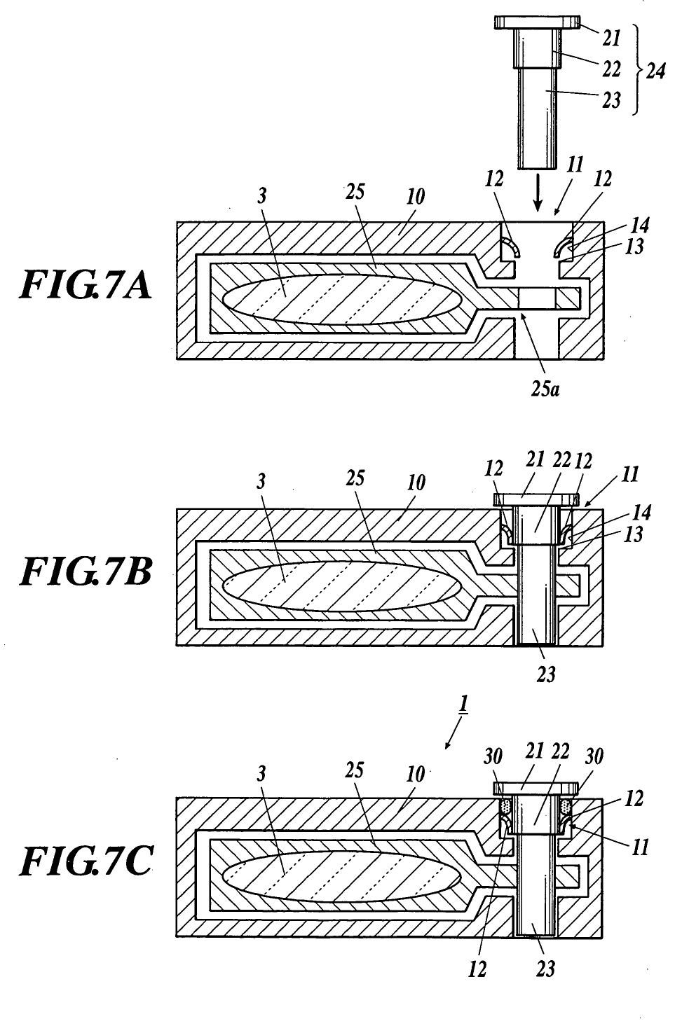

FIG. 2 is a perspective view showing a whole configuration of an imaging unit 1 in accordance with the embodiment; FIG. 3 is a perspective view showing a partial configuration of the imaging unit 1 in accordance with the embodiment; FIG. 4 is an enlarged partial view of the imaging unit 1 in accordance with the embodiment; FIG. 5 is a front view showing the imaging unit 1 in accordance with the embodiment; FIG. 6 is a side view showing the imaging unit 1 of FIG. 5; FIG. 7A is an explanation drawing showing a manufacturing process (before assembling a main body 24) of the imaging unit 1 in accordance with the embodiment; FIG. 7B is an explanation drawing showing a manufacturing process (after inserting the main body 24) of the imaging unit in accordance with an embodiment of the present invention; and FIG. 7C is an explanation drawing showing a manufacturing process (after finishing an assembling of the main body 24) of the imaging unit in accordance with the embodiment.

As shown in FIG. 2, the imaging unit 1 is arranged in a case 100 having a window 103 for shooting images, and is supported with being movable into a direction (a vertical direction and a horizontal direction) perpendicular to an axis X of lens (see FIG. 6).

Specifically, the imaging unit 1 according to the present embodiment has an image stabilizing function to cancel a fluctuation of the imaging unit 1 to a vertical direction and to a horizontal direction caused by a fluctuation by a user. The imaging unit 1 is movable to a vertical and to a horizontal direction by two extremely compact liner actuators; each of them is arranged in a direction with being able to bisect each other at right angles and in a direction perpendicular to an axis X of lens. In this embodiment, for example, two SIDMs 101 and 102 are arranged as the liner actuators. Each of the SIDMs 101 and 102 includes a main body configured by three elements: a fixed portion, a piezoelectric element and a drive shaft, being connected in this order, and a mobile object frictionally engaged with the drive shaft. Each of the SIDMs 101 and 102 is a conventional liner actuator using rapid volume changes of the piezoelectric element, inertia and a frictional force of the mobile object.

As shown in FIGS. 2 to 6, for example, the imaging unit 1 has a lens driving mechanism 20 for driving a lens 3 along a direction of the axis X of lens, and a housing 10 for housing the lens driving mechanism 20.

The lens driving mechanism 20 functions as a driving source of a zoom function (Auto-focusing function) in the direction of the axis X in the imaging unit 1. The lens driving mechanism 20 is a liner actuator i.e. SIDM, including a main body 24 and a mobile object 25 (a driven member), which movably holds the lens 3 and frictionally engaged with the drive shaft 23. The main body 24 is configured by a cylindrical drive shaft 23 (a driving member), a piezoelectric element 22 as an element for mechano-electric transduction, which drives the drive shaft 23 in an axial direction of the drive shaft 23, and a fixed portion 21 to support an end of the piezoelectric element 22, being connected in this order.

A surface of the fixed portion 21 is coated to be insulating so as to have nonconductivity, and the fixed portion 21 supports the piezoelectric element 22 arranged in the front surface side of the fixed portion 21.

The piezoelectric element 22 expands and contracts according to an applied voltage, in order to move the drive shaft 23 axially.

The drive shaft 23 moves axially according to a displacement of the piezoelectric element 23, in order to cause the mobile member 25, which is a driven member, to perform a predetermined motion.

The mobile object 25 frictionally engaged with the drive shaft 23 with being configured to fold the drive shaft 23 between the mobile object 25 and the clipping member 27, which is biased by a compression spring 26. Then, the lens driving mechanism 20 drives the drive shaft 23 forwardly and backwardly along the axis X of lens, according to an expansion and to a contraction of the piezoelectric element 22. The lens driving mechanism 20 moves the mobile member 25 frictionally engaged with the drive shaft to whichever direction of the drive shaft 23, so as to provide a traveling force for the lens 3. Incidentally, the mobile member 25 engages with a groove portion 15 formed on the housing 10 on the opposite side of an engaging portion with the drive shaft 23, and a rotation of the mobile member 25 around the axis X of lens is limited. Moreover, a location of the mobile member 25 in an axial direction of the axis X of lens is detected by a location sensor mounted in the housing 10.

The housing 10 includes a loading section 11 for loading the piezoelectric element 22 as a loading section for loading the element for mechano-electric transduction, and a pair of an anode/cathode electrical terminals 12. One end of the electrical terminal 12 is connected with the piezoelectric element 22 when the main body 24 is attached to the loading section 11.

Specifically, as shown in FIG. 5, the housing 10 is configured to be, for example, an almost rectangle shaped frame, viewed from the axial direction of the axis X of lens. The loading section 11 of the lens driving mechanism 20 is arranged at one corner of the rectangle frame. Moreover, the mobile member 25 is placed in an inner side of the housing 10, and a circular lens 3 is embedded and held in almost the center of the mobile member 25. Then, the lens 3 is held being movable to the axial direction of the axis X of lens, by the drive shaft 23 of the main body 24 that is frictionally engaged with the mobile member 25. Incidentally, a shutter unit (a light intensity controller: not shown), which is driven by a shutter driving device (a light intensity controller driving unit), is fixed on the mobile member 25.

Here, the loading section 11 and the electrical terminal 12 will be described in detail hereinbelow.

As shown in FIG. 4, for example, an opening 13 in which the drive shaft 23 is inserted in with being parallel to the axis X of lens is formed on the loading section 11. A holding section 14 for holding the piezoelectric element 22 is formed adjacent to the opening 13. Then, the drive shaft 23 of the main body 24 is inserted in the opening 13, and the piezoelectric element 22 is arranged in the holding section 14. The main body 24 of the lens driving mechanism 20 is then attached to the loading section 11 by adhering the fixed portion 21 of the main body 24 and the loading section 11.

The electrical terminal 12 exists so as to electrically connect an electrical source section controlled by a controller (not shown) of the electronic device, in which the imaging unit 1 is mounted thereon with the piezoelectric element 22. The electrical terminal 12 is a signal input section for inputting driving signal to elongate and to contract the piezoelectric element 22. Each one end of the electrical terminals 12 is projected from the holding section 14 to face with each other, and the each one end of the electrical terminals 12 is bent to be directed to a direction that the drive shaft 23 is inserted in regard to the housing 10 (see FIGS. 4 and 6). Moreover, the each one end of the electrical terminal 12 has elasticity and being biased in order to hold the piezoelectric element 22 (see FIGS. 3 and 6). Furthermore, each another end of the electrical terminal 12 is projected parallel to each other from a lower part in side surface of the housing 10 to an outward direction.

The electrical terminal 12 is formed integrally with the housing 10 by being built into the housing 10. Specifically, the electrical terminal 12 is preliminarily built into the housing 10 when the housing 10 is formed by, for example, injection molding of the thermoplastic resin (first step). The electrical terminal 12 may be formed also integrally with the housing 10 by forming a through-hole or a notch for embedding the electrical terminal 12 in a lower part of the housing 10, and by folding or by embedding the electrical terminal 12 embedded from an outside to an inside through the through-hole or the notch.

Then, the one end of the electrical terminal 12 and the piezoelectric element 22 are connected with each other by attaching the main body 24 of the lens driving mechanism 20 to the loading section 11 of the housing 10 having the electrical terminal 12 therein, formed by the above first step (second step).

Next, a method for making the imaging unit 1, namely a step for attaching the main body 24 of the SIDM to the housing 10, is described.

As shown in FIG. 7A, the mobile member 25 that holds the lens 3 is arranged inside the housing 10 on condition that the movement of the mobile member 25 to the axial direction of the axis X of lens is limited by a predetermined assembling jig.

When attaching the main body 24, which includes the fixed portion 21, the piezoelectric element 22 and the drive shaft 23, to the loading section 11, the main body 24 should be inserted into the loading section 11 so as to pass through between the pair of the one end (tip) of the electrical terminal 12.

Then, as shown in FIG. 7B, the drive shaft 23, which has passed through between the pair of the one end of the electrical terminals 12, becomes smoothly inserted into the opening 13 of the loading section 11. Moreover, when the drive shaft 23 that has passed through the opening 13 reaches the mobile member 25, the movement of which is limited by the predetermined assembling jig (not shown), the drive shaft 23 becomes engaged with an engaging portion 25a of the mobile member 25, wherein the engaging portion 25a being arranged in relation to the opening 13.

That is, the pair of electrical terminals 12 is configured to be an alignment that guides the drive shaft 23 to where the drive shaft 23 should be engaged with the mobile member 25, when the main body 24 is attached to the loading section 11.

Then, by connecting an under surface of the fixed portion 21 to an upper surface of the housing 10, the drive shaft 23 is arranged in a predetermined position in the housing 10, the piezoelectric element 22 is electrically connected with the electrical terminal 12 within the loading section 11, and the main body 24 is attached to the loading section 11 of the housing 10.

Then, as shown in FIG. 7C, a conductive adhesion bond 30 is injected from the side opening of the housing 10 into the loading section 11, the piezoelectric element 22 and the electrical terminal 12 is bonded, and the piezoelectric element 22 electrically be connected with the electrical terminal 12 (second step).

By electrically connecting the piezoelectric element 22 with the electrical terminal 12 with the conductive adhesion bond 30, the assembling of the imaging unit 1 is finished, and the imaging unit 1 is produced.

Next, an operation of the imaging unit 1 configured as mentioned above is described.

First of all, concerning the imaging unit 1, the housing 10 and the electrical terminal 12 is integrally formed on condition that the electrical terminal 12 being built into the housing 10 (first step).

Then, by inserting the drive shaft 23 into the opening 13 of the loading section 11 of the housing 10 formed by the first step, the main body 24 of the lens driving mechanism 20 is attached to the loading section 11, and the piezoelectric element 22 is attached to the electrical terminal 12 (second step).

In this regard, the lens driving mechanism 20 can be easily inserted into the housing 10, by the one end of the electrical terminal 12 being directed to the direction that the drive shaft 23 is going to be inserted into the housing 10. Moreover, the each one end of the electrical terminal 12 is certainly connected to the piezoelectric element 22, when the lens driving mechanism 20 is attached to the housing 10, by the each one end of the electrical terminal 12 being biased in order to hold the piezoelectric element 22. Furthermore, only attaching the lens driving mechanism 20 to the housing 10 enables the electrical source section for driving the imaging unit 1 be easily electrically connected to the piezoelectric element 22, by each another end of the electrical terminal 12 being projected from a side surface of the housing 10 to an outward direction.

As described above, according to the imaging unit 1 of the present embodiment, because of the configuration that the pair of the anode/cathode electrical terminal 12 that is to be connected with the piezoelectric section 22 of the lens driving mechanism 20 being formed integrally with the housing 10 with being built into the housing 10, and by each of the electrical terminal 12 being arranged to where the each one end of the electrical terminal 12 could be connected with the piezoelectric element 22, when the main body 24 of the lens driving mechanism 20 is attached to the loading section 11 of the housing 10, only attaching the lens driving mechanism 20 to the housing 10 enables the electronic device having the imaging unit 1 be easily, certainly and electrically connected to the piezoelectric element 22 of the lens driving mechanism 20.

Labor hours and the number of assembling processes in assembling the lens driving mechanism 20 into the housing 10 can be considerably reduced, for there is no need to decide a direction, a length, or a location of the FPC, when attaching the lens driving mechanism 20 to the housing 10, or further for there is no need for soldering to connect the piezoelectric element 22 with the FPC, in comparison with the case that, for example, using flexible printed circuits (FPC) to electrically connect the piezoelectric element 22 of the lens driving mechanism 20 with the electronic device having the imaging unit 1. Therefore, the imaging unit 1 has become easy to assemble.

Moreover, because the each one end of the electrical terminals 12 is directed to a direction that the drive shaft 23 be inserted in regard to the housing 10, the lens driving mechanism 20 can be easily inserted into the housing 10. Moreover, because the each one end of the electrical terminal 12 is biased in order to hold the piezoelectric element 22, each of the electrical terminals 12 can be certainly connected to the piezoelectric element, when the lens driving mechanism 20 is attached to the housing 10.

Moreover, by the another end of the electrical terminal 12 is projected from the side face of the housing 10 to the outward direction, only attaching the lens driving mechanism 20 to the housing 10 enables the electronic device having the imaging unit 1 be easily, certainly and electrically connected with the piezoelectric element 22.

Moreover, only attaching the main body 24 of the lens driving mechanism 20 to the loading section 11 of the housing 10, which is formed integrally with the electrical terminal 12 at the first step, at the second step, enables the piezoelectric element 22 of the lens driving mechanism 20 be easily connected with the electrical terminal 12. Therefore, it is easy to assemble the imaging unit 1, because the lens driving mechanism 20 can be easily attached to the housing 10.

Incidentally, the imaging unit 1 may be formed integrally with an electrical terminal (not shown) for a shutter driving mechanism by being built into the housing 10. That is, for example, because the shutter driving mechanism has a solenoid for rotating a blade of a shutter unit (not shown) in a plane perpendicular to the axis X of lens of the imaging unit 1, an electrical terminal for inputting a driving signal into a solenoid valve for driving the solenoid could be easily formed integrally with the housing 10 as well as the electrical terminal 12. This enables an assembling of the shutter driving mechanism to the housing 10 easily to be done.

Moreover, each of the electrical terminal 12 may not be limited to the shape illustrated by an example in the above described embodiment but may be formed in any shape. That is, for example, the electrical terminal 12 maybe formed with being projected to the direction that the main body 24 should be inserted in, at a slant. Moreover, only any one end of the electrical terminals 12 may be projected from the holding section 14 and directed to the direction that the drive shaft 23 should be inserted in, with being biased so as to clip the piezoelectric element 22. The other end of the electrical terminal 12 may be arranged in the same plane as a facing surface of the holding section 14 with being able to contact with the piezoelectric element 22.

Moreover, the driving member should not be limited to the drive shaft 23, but may be formed by any member as long as the member can be connected with the piezoelectric element 22 and can be moved to provide with traveling force to the driven member. Similarly, the driven member may be formed by any member as long as the member can hold a lens, frictionally engaged with the driving member, and can be moved by the driving member.

That is, for example, a magnet may be applied to as the driving member, in place of the drive shaft 23, to be connected with the piezoelectric element 22, while a metallic material may be arranged on the mobile member 25 as a driven member, to be connected with the magnet to support the mobile member 25. In this case, if the magnet is moved forwardly or backwardly along the axis X of lens by a slow expansion and contraction of the piezoelectric element 22, the mobile member 25 that is hold by the magnet through the metallic material is moved to any one direction along the axis X of lens. Moreover, if the magnet is moved forwardly or backwardly along the axis X of lens by a rapid expansion and contraction of the piezoelectric element 22, binding force between the magnet and the metallic material becomes broken up and only the magnet is moved with the mobile member 25 still be hold in the same place.

Moreover, an element such as, for example, an electrostrictive element that expands and contracts according to an applied voltage can be applied to as an element for mechano-electric transduction, other than the piezoelectric element 22 disclosed in this embodiment.

The entire disclosure of Japanese Patent Application No. 2007-185750 filed on Jul. 17, 2007 including description, claims, drawings and summary are incorporated herein by reference in its entirely.

Although various exemplary embodiments have been shown and described, the invention is not limited to the embodiments shown. Therefore, the scope of the invention is intended to be limited solely by the scope of the claims that follow.

What is claimed is:

1. A drive unit, comprising:
an element for mechano-electric transduction;
a driving member for causing a driven member to perform a predetermined motion according to a displacement of the element; and
a housing to house the driving member;
wherein, the housing includes
an electrical terminal, and
a loading section for loading the element,
the electrical terminal being configured to be connectable with the element when the element is attached to the loading section.

2. The drive unit according to claim 1, wherein the electrical terminal is built into the housing with being configured integral with the housing.

3. The drive unit according to claim 2, wherein one end of the electrical terminal is directed to the direction to which the element is inserted in regard to the housing, and that the end of the electrical terminal is biased so as to be able to hold the element.

4. The drive unit according to claim 3, wherein another end of the electrical terminal is projected to an outward direction of the housing from an under surface or a side surface of the housing.

5. A method for making the drive unit of claim 2, comprising the steps of:
a first step for configuring the housing integrally with the electrical terminal; and
a second step for connecting the one end of the electrical terminal to the element by attaching the element to the loading section of the housing obtained by the first step.

6. The drive unit according to claim 1, wherein one end of the electrical terminal is directed to the direction to which the element is inserted in regard to the housing, and that the end of the electrical terminal is biased so as to be able to hold the element.
